(19) United States
(12) Patent Application Publication
(10) Pub. No.: US 2010/0245146 A1
(43) Pub. Date: Sep. 30, 2010

(54) INTELLIGENT ANALOG-DIGITAL CONVERTER CHIP

(76) Inventors: Bo-Jau Kuo, Taipei City (TW); Ching-Hsiu Yang, Taipei City (TW)

Correspondence Address: Muncy, Geissler, Olds & Lowe, PLLC, 4000 Legato Road, Suite 310, FAIRFAX, VA, 22033, US

(21) Appl. No.: 12/431,329

(22) Filed: Apr. 28, 2009

(30) Foreign Application Priority Data
Mar. 31, 2009 (TW) 098110647

(51) Int. Cl. H03M 1/12

(52) U.S. Cl. 341/155

(57) ABSTRACT

The present invention discloses an intelligent analog-digital converter chip. It mainly comprises an amplifier, a filter, an analog/digital converter and a central processing unit. The main feature of the present invention is that it can directly connect to the micro-controller and computer, and possess the advantages of lower power consumption, chip area reduction and stability enhancement. It plays a key component for the application of computer, communication and consumer electronic products.

### BACKGROUND OF THE INVENTION

1. Field of the Invention

The present invention generally relates to an analog-digital converter chip, especially for an intelligent analog-digital converter chip, having a Universal Asynchronous Receiver/Transmitter (UART) interface to connect directly with a micro-controller or a personal computer (PC), The chip integrate the hardware and the software that are needed in the analog-digital transformation on single chip, which can be used for the application of computer, communication and consumer electronic products.

2. Description of the Related Art

Sympathetic nerves and parasympathetic nerves, both of which belong to human autonomic nervous system, are closely related to the daily operation of a human body. Autonomic imbalance may induce various acute and chronic diseases, for example, heart disease, hypertension, etc., and may even lead to a sudden death, if serious. Even healthy individuals suffering from autonomic disorders may have palpitation, dyspnea (shortness of breath), gastrointestinal disorders, insomnia, etc. Hence, the protection for autonomic nervous system is not only an important issue in medicine but also a personal concern to an individual everyday. Living quality depends on how well our autonomic nervous system functions. Signs and symptoms of certain severe diseases at an early stage are attributable to autonomic disorders. Hence, early detection of autonomic disorder in an individual or a patient is likely to lessen or even prevent tragedies.

A normal adult's heart rate is about 70 beats per minute. The regular beating originates in a pacemaking system of the heart, which comprises sinoatrial node (SA node), atrioventricular node (AV node) and various kinds of nerve fibers. The pacemaking system is very precise so as to maintain the most essential rhythm of life. Nevertheless, to cope with various environments inside outside human bodies, human bodies are equipped with the autonomic nervous system including the sympathetic nervous system and the parasympathetic nervous system for regulation of heart rate. The former increases the heart rate, whereas the latter decreases it. Owing to the interaction of the two nervous systems, heart rate is kept in an optimal state of equilibrium. In addition to their different effects, the two nervous systems function at different speeds. The sympathetic nerves work slowly, and the parasympathetic nerves (especially the vagus nerve, which controls heart rate) function fast. Mankind has known the discrepancy between the respective speeds of these two different kinds of nervous systems for a long time. However, in the past, the analytical instruments were not sophisticated enough to enable the evaluation of this characteristic or persuade people that it is worth using.

There are many kind of physiology signals within the body of human being, for example, heart beat, weight, body temperature, breathing and blood pressure etc. These signals are the important configuration of the healthy. Therefore, if these signals can be effectively transferred into digital, the applications of medicine, research and livehood can be effectively improved. Nowadays, most of the analog/digital converter sold in the market can be generally classified into parallel interface and series interface, wherein the series interface can be more divided into SPI or C2D system. Nevertheless, no matter the parallel interface or the series interface, it still needs the micro-controller transformation, i.e. transfer to UART or RS232, as connecting to the PC or micro-controller. Actually, it is not convenient for a PC user.

U.S. Pat. No. 7,250,880 issued to Hurrell et al., entitled “Analog to digital converter”, discloses that an analog to digital converter using a plurality of conversion engines acting in a co-operative state for a first part of a conversion cycle to allow multiple bits to be examined at each trial. However, it is not yet found the interface connection between to PC or micro-controller. According above problems, the related filed need a new amplifier to overcome the disadvantage of the prior art.

### BRIEF SUMMARY OF THE INVENTION

It is an objective of the present invention to provide an intelligent analog-digital converter chip, having a UART interface, that can be directly connected to the micro-controller and computer. It makes the program designer use the analog-digital function by using software instruction and connection of UART or RS232.

It is the second objective of the present invention to provide an apparatus with an intelligent analog-digital converter chip. It can be applied for any kinds of new type virtuality and performed the transportation and connection with long distance. It makes the loop full in digital, consume lower power, reduce of chip area and enhance the stability.

To achieve the above objectives, the present invention provides an intelligent analog-digital converter chip, having a UART interface to connect directly with a micro-controller or a computer, comprising an amplifier, a filter, an analog/digital converter, and a central processing unit, where the amplifier is electrically connected to an analog signal and used for receiving and amplifying the analog signal, the filter is electrically connected to the amplifier and used for filtering the noises of output signal of the amplifier, the analog/digital converter is electrically connected to the filter and used for converting the output signal of the filter from analog into digital, and the central processing unit is electrically connected to the analog/digital converter and used for computing the output signal of the analog/digital converter, outputting a resulting signal and receiving a control signal.

According to one aspect of the present invention, the output signal of the filter is digitized by using the settings of start, sampling frequency, channel number, output-data format, sampling-bit and end for the analog/digital convert.

According to one aspect of the present invention, the resulting signal further comprising: a data length, used for describing the length of the resulting signal; and a byte stream, used for describing the content of the resulting signal, wherein the length of the byte stream is assigned by the data length.

According to one aspect of the present invention, the resulting signal is output in the parallel form or series form.

According to one aspect of the present invention, the intelligent analog-digital converter chip is controlled by a control signal.

According to one aspect of the present invention, the control signal is provided by a central process unit and a micro-controller.

To achieve another above objectives, the present invention provides an apparatus with the intelligent analog-digital converter chip comprising a plurality of intelligent analog-digital converter chips, and a plurality of central processing units or a plurality of micro-controllers. At least one of the plurality of intelligent analog-digital converter chips has a UART interface to connect directly with a micro-controller or a computer. The plurality of intelligent analog-digital converter chips are used for analyzing the signal of analog-digital converter, outputting a plurality of resulting signals and receiving a plurality of control signals and electrically connected to the plurality of intelligent analog-digital converter chips, and the plurality of central processing units or the plurality of micro-controllers are used for receiving and computing the plurality of resulting signals which are output by the plurality of intelligent analog-digital converter chips, and outputting a plurality of control signals.

According to one aspect of the present invention, the plurality of intelligent analog-digital converter chips are realized by using the Bipolar Junction Transistor (BJT), Heterojunction Bipolar Transistor (HBT), High Electronic Mobility Transistor (HEMT), Pseudomorphic HEMT (PHEMT), Complementary Metal Oxide Semiconductor Filed Effect Transistor (CMOS) and Laterally Diffused Metal Oxide Semiconductor Filed Effect Transistor (LDMOS). According to one aspect of the present invention, the transistors are realized by using the 0.18 μm [symbol] 0.13 μm [symbol] 0.09 μm [symbol] 0.045 μm or the advanced process.

### BRIEF DESCRIPTION OF THE DRAWINGS

All the objects, advantages, and novel features of the invention will become more apparent from the following detailed descriptions when taken in conjunction with the accompanying drawings.

FIG. 1 shows a schematic of an apparatus with the intelligent analog-digital converter chip according to the first embodiment of the present invention;

FIG. 2 shows a table for the setting of digital process and output-data format of chip in this invention; and

FIG. 3 shows the applications of the apparatus with intelligent analog-digital converter chip in this invention.

### DETAILED DESCRIPTION OF THE INVENTION

Although the invention has been explained in relation to several preferred embodiments, the accompanying drawings and the following detailed descriptions are the preferred embodiment of the present invention. It is to be understood that the following disclosed descriptions will be examples of present invention, and will not limit the present invention into the drawings and the special embodiment.

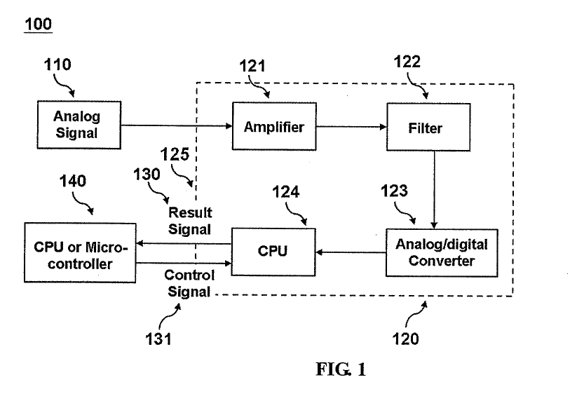

To understand the spirit of the present invention, referring to FIG. 1, it shows the schematic of an apparatus with an intelligent analog-digital converter chip 100, wherein the intelligent analog-digital converter chip, having a UART interface 125 to connect directly with a micro-controller or a computer 140, mainly comprises an amplifier 121, a filter 122, an analog/digital converter 123, and a central processing unit 124. The amplifier 121 used for amplifying an analog signal 110, the filter 122, electrically connected to the amplifier 121, used for filtering the noises of output signal of the amplifier 121, the analog/digital converter 123, electrically connected to the filter 122, used for digitizing the output signal of the filter 122, and the central processing unit 124, electrically connected to the analog/digital converter 123, used for computing the output signal of the analog/digital converter 123 and outputting a resulting signal 130 to the micro-controller or the computer 140. The operation of the intelligent analog-digital converter chip 120 is described as followings: an analog signal 110 is input into the intelligent analog-digital converter chip 120 and amplified by the amplifier 121, and then input into the filter 122. The filter 122 filters the noises of output signal of the amplifier 121, and the output signal of the filter 122 is converted from analog into digital by means of the analog/digital converter 123, and then input into central processing unit 124. The analog/digital converter 123 executes a series of settings to carry out the transformation of analog/digital signals (for further details, please refer to later description). Finally, the central processing unit 124 outputs the resulting signal 130. Moreover, the resulting signal 130 is the output signal of the intelligent analog-digital converter chip 120, and it can be output in the parallel form or series form and the intelligent analog-digital converter chip 120 is controlled by the control signal 131 provided by a central processing units or a micro-controllers 140.

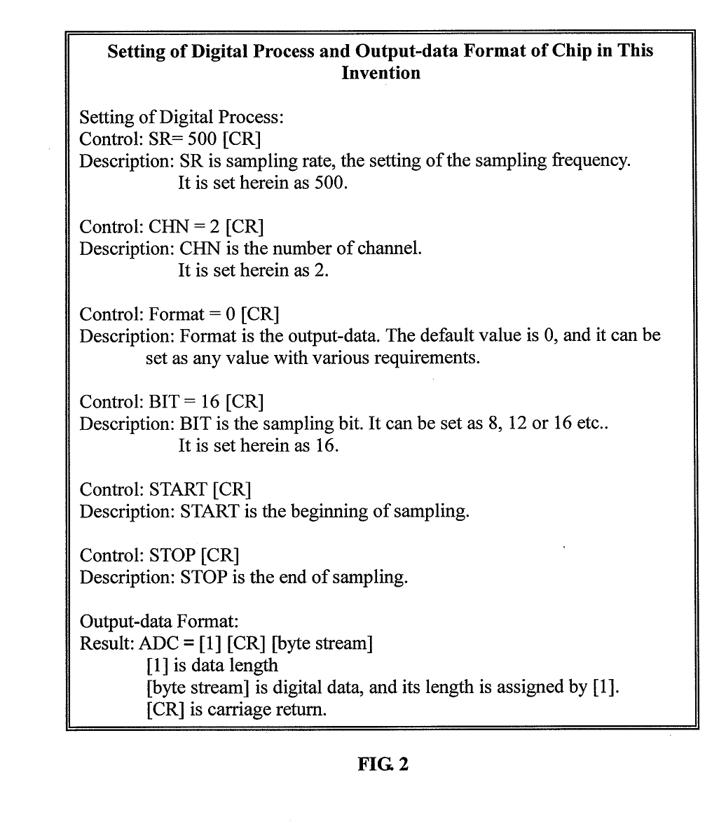

Now referring to FIG. 2, it shows a table of the settings of transformation of analog/digital signals and output-data format of chip in the present invention. It is noted that the settings of transformation of analog/digital signals are start, sampling frequency, channel number, output-data format, sampling-bit and end which are executed by the analog/digital converter. In the present invention, the settings of sampling frequency, channel number and output-data format are set as, but are not limited to, 500, 2, 0 and 16, respectively. After execute the settings above, the intelligent analog-digital converter chip 120 outputs the resulting signal 130. Moreover, the resulting signal 130 further comprising a data length, used for describing the length of data, and a byte stream, used for describing the content of the resulting signal 130, wherein the length of the byte stream is assigned by the data length.

According to the present invention, the circuit of the intelligent analog-digital converter chip 120 can be implemented by using: Bipolar Junction Transistor (BJT), Heterojunction Bipolar Transistor (HBT), High Electronic Mobility Transistor (HEMT), Pseudomorphic HEMT (PHEMT), Complementary Metal Oxide Semiconductor Filed Effect Transistor (CMOS) and Laterally Diffused Metal Oxide Semiconductor Filed Effect Transistor (LDMOS). Preferably, PHEMT is suitable for the intelligent analog-digital converter chip 120 in the microwave to millimeter wave range. Semiconductor materials broadly applicable to the intelligent analog-digital converter chip include: silicon, silicon-on-insulator (SOI), silicon-germanium (SiGe), gallium arsenide (GaAs), indium phosphide (InP) and silicon-germanium-carbon (SiGe—C). Preferably, the intelligent analog-digital converter chip 120 is designed with resistive shunt-feedback PHEMT transistors on semiconductor substrate of Al—In—GaAs compound. Depending on the required noises and reliability of the intelligent analog-digital converter chip 120. Moreover, the transistors mentioned above can be realized by using the 0.18 μm [symbol] 0.13 μm [symbol] 0.09 μm [symbol] 0.045 μm or the advanced process.

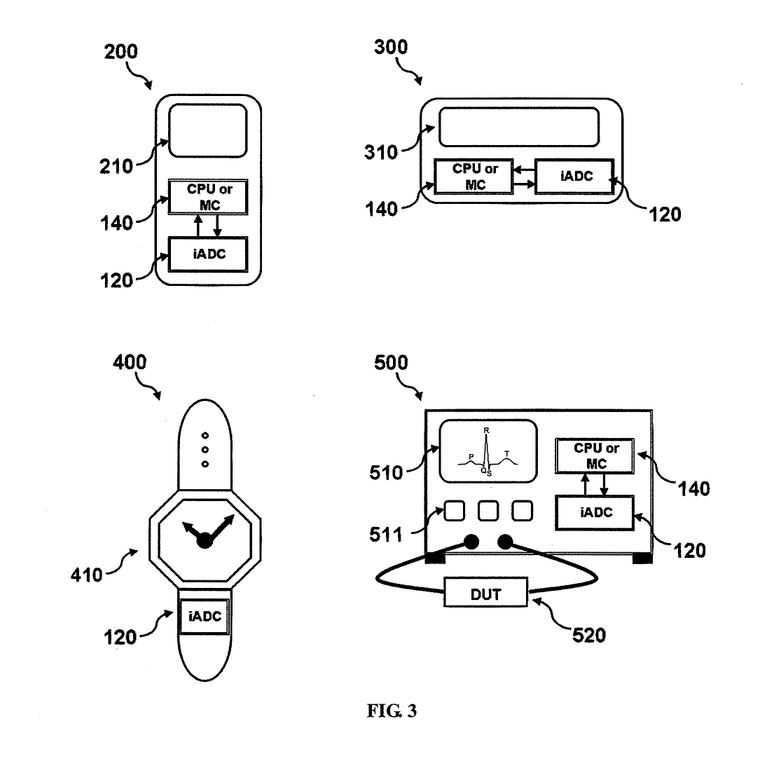

According to the present invention, refereeing to FIG. 3, the intelligent analog-digital converter chip 120 can be, but not limited to, applied for the mobile devices 200, computers, personal media players 300 and medical instruments 500, which require the transformation of analog/digital signals. Moreover, the mobile devices can be a cell phone, a personal digital assistant and even the electrical watch 400, and the medical instruments can be a blood pressure measurement, a glucosemeter, a thermometer, thermal scan, physiology detector, activity detector and electrocardiogram signal detector. In addition, the device under test 520 provides any kind of signal, and the medical instruments 500 more comprise, buttons 511, used for controlling for the medical instruments 500. All of them are mainly comprised of the intelligent analog-digital converter chip 120 and the monitors 210 310 410 510 which used for showing the information for the user.

The present invention further provides an apparatus 100 with the intelligent analog-digital converter chip 120. The apparatus 100 comprises a plurality of intelligent analog-digital converter chips and a plurality of central processing units or a plurality of micro-controllers, electrically connected to the plurality of intelligent analog-digital converter chips. The plurality of intelligent analog-digital converter chips are the disclosed intelligent analog-digital converter chip 120 in the first embodiment, used for used for analyzing the transformation of analog-digital process, outputting a plurality of resulting signals and receiving a plurality of control signals. The plurality of central processing units or the plurality of micro-controllers are used for receiving, computing the plurality of resulting signals, which are output by the plurality of intelligent analog-digital converter chips, and outputting the plurality of control signals. It is noted that at least one of the plurality of intelligent analog-digital converter chips has a UART interface to connect directly with a micro-controller or a computer.

According to the present invention, the apparatus with intelligent analog-digital converter chip can be implemented by using: Bipolar Junction Transistor (BJT), Heterojunction Bipolar Transistor (HBT), High Electronic Mobility Transistor (HEMT), Pseudomorphic HEMT (PHEMT), Complementary Metal Oxide Semiconductor Filed Effect Transistor (CMOS) and Laterally Diffused Metal Oxide Semiconductor Filed Effect Transistor (LDMOS). Preferably, PHEMT is suitable for the intelligent analog-digital converter chip 120 in the microwave to millimeter wave range. Semiconductor materials broadly applicable to the intelligent analog-digital converter chip include: silicon, silicon-on-insulator (SOI), silicon-germanium (SiGe), gallium arsenide (GaAs), indium phosphide (InP) and silicon-germanium-carbon (SiGe—C). Preferably, the intelligent analog-digital converter chip 120 is designed with resistive shunt-feedback PHEMT transistors on semiconductor substrate of Al—In—GaAs compound. Depending on the required noises and reliability of the intelligent analog-digital converter chip 120. Moreover, the transistors mentioned above can be realized by using the 0.18, μm [symbol] 0.13 μm [symbol] 0.09 μm [symbol] 0.045 μm or the advanced process.

According to present invention, the advantage of the apparatus with intelligent analog-digital converter chip 100 can be directly connected to the micro-controller and computer. It makes the program designer can use the analog-digital function by a software instruction and a connection of UART or RS232.

Another advantage of the apparatus with intelligent analog-digital converter chip 100 is that it can be applied for any kinds of new type virtuality and performed the transportation and connection with long distance. The technology makes the loop full in digital, and possesses the advantages of lower power consumption, chip area reduction and stability enhancement.

Although the invention has been explained in relation to its preferred embodiment, it is not used to limit the invention. It is to be understood that many other possible modifications and variations can be made by those skilled in the art without departing from the spirit and scope of the invention as hereinafter claimed.

What is claimed is:

1. An intelligent analog-digital converter chip, having a UART interface to connect directly with a micro-controller or a computer, mainly comprising:
an amplifier, used for receiving and amplifying an analog signal;
a filter, electrically connected to the amplifier, used for filtering the noises of output signal of the amplifier;
an analog/digital converter, electrically connected to the filter, used for digitizing the output signal of the filter; and
a central processing unit, electrically connected to the analog/digital converter, used for computing the output signal of the analog/digital converter and outputting a resulting signal to the micro-controller or the computer.

2. An intelligent analog-digital converter chip as claimed in claim 1, wherein the output signal of the filter is digitized by using the settings of start, sampling frequency, channel number, output-data format, sampling-bit and end for the analog/digital converter.

3. An intelligent analog-digital converter chip as claimed in claim 1, wherein the resulting signal further comprising:
a data length, used for describing the length of the resulting signal; and
a byte stream, used for describing the content of the resulting signal.
wherein the length of the byte stream is assigned by the data length.

4. An intelligent analog-digital converter chip as claimed in claim 1, wherein the resulting signal is output in the parallel form or series form.

5. An intelligent analog-digital converter chip as claimed in claim 1, wherein the intelligent analog-digital converter chips is controlled by a control signal.

6. An the intelligent analog-digital converter chip as claimed in claim 5, wherein the control signal is provided by a central processing units or a micro-controller.

7. An intelligent analog-digital converter chip as claimed in claim 1, wherein the intelligent analog-digital converter chip is applied for the mobile devices, computers, personal media players and medical instruments.

8. An intelligent analog-digital converter chip as claimed in claim 7, wherein the mobile devices is a cell phone, a personal digital assistant and a personal media player.

9. An intelligent analog-digital converter chip as claimed in claim 7, wherein the medical instruments is a blood pressure measurement, a glucosemeter, a thermometer, thermal scan, physiology detector, activity detector and electrocardiogram signal detector.

10. An apparatus with the intelligent analog-digital converter chip, mainly comprising:
a plurality of intelligent analog-digital converter chips, used for analyzing the transformation of analog-digital process, outputting a plurality of resulting signals and receiving a plurality of control signals; and
a plurality of central processing units or a plurality of micro-controllers, electrically connected to the plurality of intelligent analog-digital converter chips, used for receiving, computing the plurality of resulting signals, which are output by the plurality of intelligent analog-digital converter chips, and outputting the plurality of control signals;
where at least one of the plurality of intelligent analog-digital converter chips has a UART interface to connect directly with a micro-controller or a computer.

11. An apparatus with the intelligent analog-digital converter chip as claimed in claim 10, wherein the resulting signal further comprising:
a plurality of data lengths, used for describing the length of the resulting signals; and
a plurality of byte streams, used for describing the content of the resulting signals.
wherein the length of the a plurality of byte streams are assigned by the a plurality of data lengths.

12. An apparatus with the intelligent analog-digital converter chip as claimed in claim 10, wherein the plurality of resulting signals are output in the parallel form or series form.

13. An apparatus with the intelligent analog-digital converter chip as claimed in claim 10, wherein the plurality of intelligent analog-digital converter chips are controlled by the a plurality of control signals.
